(19) United States
(12) Patent Application Publication
(10) Pub. No.: US 2023/0275560 A1
(43) Pub. Date: Aug. 31, 2023

(54) ACOUSTIC WAVE DEVICE

(71) Applicant: Murata Manufacturing Co., Ltd., Nagaokakyo-shi (JP)

(72) Inventor: Shintaro KUBO, Nagaokakyo-shi (JP)

(21) Appl. No.: 18/195,428

(22) Filed: May 10, 2023

Related U.S. Application Data
(63) Continuation of application No. PCT/JP2021/041099, filed on Nov. 9, 2021.
(60) Provisional application No. 63/112,241, filed on Nov. 11, 2020.

(51) Int. Cl. H03H 9/08; H03H 3/02; H03H 9/02; H03H 9/13; H03H 9/17

(52) U.S. Cl. CPC H03H 9/08; H03H 3/02; H03H 9/02031; H03H 9/02228; H03H 9/13; H03H 9/173; H03H 9/176; H03H 2003/021

(57) ABSTRACT

An acoustic wave device includes a support including a support substrate, a piezoelectric layer on the support, and an excitation electrode on the piezoelectric layer. A hollow portion is provided in the support and overlaps with at least a portion of the excitation electrode in plan view. The support includes a cavity opening on a side of the piezoelectric layer, and an inner wall surface connected to the cavity and facing the hollow portion. A functional film is provided on at least a portion of the inner wall surface and has an electromagnetic-wave absorption capacity in a wavelength range from about 0.2 µm to about 1.2 µm inclusive.

### CROSS REFERENCE TO RELATED APPLICATIONS

This application claims the benefit of priority to Provisional Application No. 63/112,241 filed on Nov. 11, 2020 and is a Continuation Application of PCT Application No. PCT/JP2021/041099 filed on Nov. 9, 2021. The entire contents of each application are hereby incorporated herein by reference.

### BCAKGROUND OF THE INVENTION

### 1. Field of the Invention

The present invention relates to an acoustic wave device.

### 2. Description of the Related Art

Conventionally, acoustic wave devices have been widely used for filters of cellular phones, for example. International Publication No. 2013/021948 discloses an example of an acoustic wave device using plate waves. In this acoustic wave device, a LiNbO₃ substrate is provided on a support body. A through hole is formed in the support body. An interdigital transducer (IDT) electrode is provided on the LiNbO₃ substrate at a portion of the LiNbO₃ substrate facing the through hole.

In the acoustic wave device described in International Publication No. 2013/021948, a hollow portion such as a through hole is formed so as to overlap with an IDT electrode in plan view. In this configuration, a region in which the IDT electrode is provided in the LiNbO₃ substrate is not in contact with the support body and therefore, a heat dissipation performance may be degraded.

### SUMMARY OF THE INVENTION

Preferred embodiments of the present invention provide acoustic wave devices that each improve heat dissipation performance.

An acoustic wave device according to a preferred embodiment of the present invention includes a support that includes a support substrate, a piezoelectric layer on the support, and an excitation electrode on the piezoelectric layer. A hollow portion is provided in the support and overlaps with at least a portion of the excitation electrode in plan view. The support includes a cavity which opens on a side of the piezoelectric layer, and an inner wall surface connected to the cavity and facing the hollow portion. A functional film is provided on at least a portion of the inner wall surface and having an electromagnetic-wave absorption capacity in a wavelength range from about 0.2 µm to about 1.2 µm inclusive.

An acoustic wave device according to a preferred embodiment of the present invention includes a support that includes a support substrate, a piezoelectric layer on the support, and an excitation electrode on the piezoelectric layer. A hollow portion is provided in the support and overlaps with at least a portion of the excitation electrode in plan view. The support includes a cavity which opens on a side of the piezoelectric layer, and an inner wall surface connected to the cavity and facing the hollow portion. A functional film is provided on at least a portion of the inner wall surface. Emissivity of the functional film is higher than emissivity of the inner wall surface of the support.

An acoustic wave device according to a preferred embodiment of the present invention includes a support that includes a support substrate, a piezoelectric layer on the support, and an excitation electrode on the piezoelectric layer. A hollow portion is provided in the support and overlaps with at least a portion of the excitation electrode in plan view. The support includes a cavity which opens on a side of the piezoelectric layer, and an inner wall surface connected to the cavity and facing the hollow portion. A functional film is provided on at least a portion of the inner wall surface. The functional film includes graphene, carbon nanotubes, or diamond-like carbon.

According to preferred embodiments of the present invention, heat dissipation performance is improved.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is an elevational cross-sectional view of an acoustic wave device according to a first preferred embodiment of the present invention.

FIG. 2 is a plan view of the acoustic wave device according to the first preferred embodiment of the present invention.

FIG. 3 is an elevational cross-sectional view of an acoustic wave device according to a first modification of the first preferred embodiment of the present invention.

FIG. 4 is an elevational cross-sectional view of an acoustic wave device according to a second modification of the first preferred embodiment of the present invention.

FIG. 5 is a plan view of an acoustic wave device according to a third modification of the first preferred embodiment of the present invention.

FIGS. 6A to 6C are elevational cross-sectional views for explaining a concave portion forming process and a functional film forming process in an example of a method for manufacturing an acoustic wave device according to the first preferred embodiment of the present invention.

FIGS. 7A to 7C are elevational cross-sectional views for explaining a functional film patterning process, a piezoelectric substrate bonding process, and a piezoelectric layer grinding process in an example of a method for manufacturing an acoustic wave device according to the first preferred embodiment of the present invention.

FIG. 8 is an elevational cross-sectional view of an acoustic wave device according to a second preferred embodiment of the present invention.

FIG. 9 is an elevational cross-sectional view of an acoustic wave device according to a modification of the second preferred embodiment of the present invention.

FIG. 10 is an elevational cross-sectional view of an acoustic wave device according to a third preferred embodiment of the present invention.

FIG. 11 is an elevational cross-sectional view of an acoustic wave device according to a fourth preferred embodiment of the present invention.

FIG. 12 is an elevational cross-sectional view of an acoustic wave device according to a fifth preferred embodiment of the present invention.

FIGS. 13A to 13E are elevational cross-sectional views for explaining an example of a method for manufacturing an acoustic wave device according to the fifth preferred embodiment of the present invention.

FIG. 14 is an elevational cross-sectional view of an acoustic wave device according to a modification of the fifth preferred embodiment of the present invention.

FIG. 15 is an elevational cross-sectional view of an acoustic wave device according to a sixth preferred embodiment of the present invention.

FIG. 16A is a simplified perspective view illustrating an outer appearance of an acoustic wave device using bulk waves in thickness sliding mode, and FIG. 16B is a plan view illustrating an electrode structure on a piezoelectric layer.

FIG. 17 is a sectional view of a portion taken along an A-A line of FIG. 16A.

FIG. 18A is a schematic elevational cross-sectional view for explaining Lamb waves that propagate through a piezoelectric film of an acoustic wave device, and FIG. 18B is a schematic elevational cross-sectional view for explaining bulk waves in a thickness sliding mode that propagate through a piezoelectric film in an acoustic wave device.

FIG. 19 is a diagram illustrating an amplitude direction of bulk waves in the thickness sliding mode.

FIG. 20 is a diagram illustrating resonance characteristics of an acoustic wave device using bulk waves in the thickness sliding mode.

FIG. 21 is a diagram illustrating a relationship between d/p and a fractional bandwidth as a resonator when a distance between centers of mutually-adjacent electrodes is p and a thickness of a piezoelectric layer is d.

FIG. 22 is a plan view of an acoustic wave device using bulk waves in the thickness sliding mode.

FIG. 23 is a diagram illustrating resonance characteristics of an acoustic wave device of a reference example with spurious responses.

FIG. 24 is a diagram illustrating a relationship between fractional bandwidths and phase rotation amounts of impedance of spurious which is standardized at 180 degrees as magnitudes of spurious responses.

FIG. 25 is a diagram illustrating a relationship between d/2p and a metallization ratio MR.

FIG. 26 is a diagram showing a map of a fractional bandwidth with respect to Euler angles (0°, θ, ψ) of LiNbO₃, which is obtained by approximating d/p to 0 as much as possible.

FIG. 27 is a partial cutout perspective view for explaining an acoustic wave device using Lamb waves.

### DETAILED DESCRIPTION OF THE PREFERRED EMBODIMENTS

The present invention will be clarified below by describing preferred embodiments of the present invention with reference to the accompanying drawings.

Each of the preferred embodiments described in the present specification is exemplary and configurations can be partially exchanged or combined with each other between different preferred embodiments.

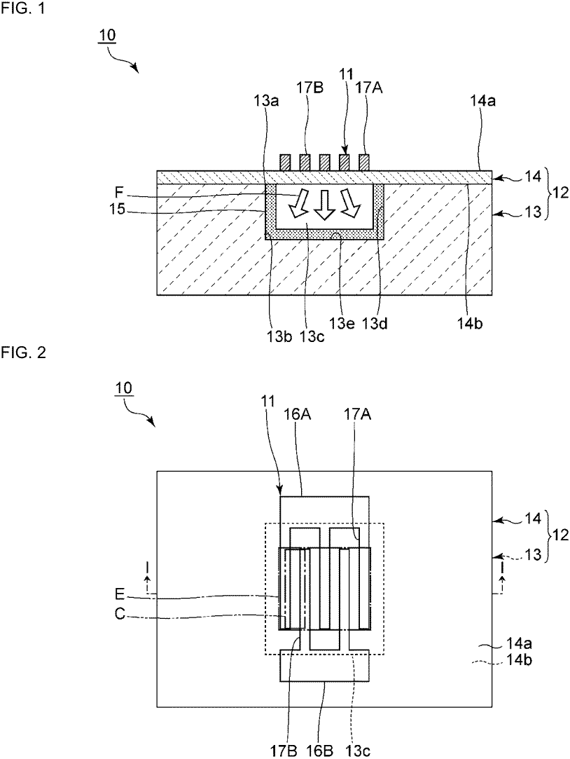

FIG. 1 is an elevational cross-sectional view of an acoustic wave device according to a first preferred embodiment of the present invention. FIG. 2 is a plan view of the acoustic wave device according to the first preferred embodiment. FIG. 1 is a sectional view taken along an I-I line of FIG. 2.

An acoustic wave device 10 includes a piezoelectric board 12 and an IDT electrode 11 defining and functioning as an excitation electrode, as illustrated in FIG. 1. The piezoelectric board 12 includes a support 13 and a piezoelectric layer 14. In the present preferred embodiment, the support 13 includes only a support substrate. However, the support 13 may be a multilayer body including, for example, a support substrate and a dielectric layer.

A hollow portion 13c is provided in the support 13. The piezoelectric layer 14 covers the hollow portion 13c of the support 13.

The piezoelectric layer 14 includes a first main surface 14a and a second main surface 14b. The first main surface 14a and the second main surface 14b are opposed to each other. The second main surface 14b is the main surface including the support 13 thereon. The piezoelectric layer 14 is, for example, a lithium niobate layer in the present preferred embodiment. More specifically, the piezoelectric layer 14 is, for example, a LiNbO₃ layer. However, the piezoelectric layer 14 may be, for example, a lithium tantalate layer such as a LiTaO₃ layer.

The support 13 includes a cavity 13a and an inner wall surface 13b. The cavity 13a is a portion opening on the side including the piezoelectric layer 14. The inner wall surface 13b is a surface that is connected to the cavity 13a and faces the hollow portion 13c. The inner wall surface 13b includes a side wall surface 13d and a bottom surface 13e in the present preferred embodiment. The side wall surface 13d is connected with the cavity 13a and the bottom surface 13e. The side wall surface 13d extends in parallel or substantially in parallel to a direction in which the support 13 and the piezoelectric layer 14 are laminated. However, the extending direction of the side wall surface 13d is not limited to the one described above. The bottom surface 13e is opposed to the piezoelectric layer 14. The bottom surface 13e is parallel or substantially parallel to the second main surface 14b of the piezoelectric layer 14. However, the relationship between the bottom surface 13e and the second main surface 14b is not limited to the one described above.

As illustrated in FIG. 2, the IDT electrode 11 is provided on the first main surface 14a of the piezoelectric layer 14. The IDT electrode 11 includes a first busbar 16A, a second busbar 16B, a plurality of first electrode fingers 17A, and a plurality of second electrode fingers 17B. The first electrode finger 17A is a first electrode. The plurality of first electrode fingers 17A are periodically arranged. One end of each of the plurality of first electrode fingers 17A is connected to the first busbar 16A. The second electrode finger 17B is a second electrode. The plurality of second electrode fingers 17B are periodically arranged. One end of each of the plurality of second electrode fingers 17B is connected to the second busbar 16B. The plurality of first electrode fingers 17A and the plurality of second electrode fingers 17B are interdigitated. The IDT electrode 11 may include a single-layer metal film or may include a multilayer metal film.

Hereinafter, the first electrode finger 17A and the second electrode finger 17B will be sometimes referred to as merely the electrode finger. When a direction in which mutually-adjacent electrode fingers are opposed to each other is defined as an electrode finger opposing direction and a direction in which a plurality of electrode fingers extend is defined as an electrode finger extending direction, the electrode finger extending direction is orthogonal or substantially orthogonal to the electrode finger opposing direction in the present preferred embodiment.

At least a portion of the IDT electrode 11 defining and functioning as an excitation electrode overlaps with the hollow portion 13c in plan view. The plan view in the present specification indicates a direction viewed from the upper side in FIG. 1.

In the IDT electrode 11, a region in which mutually-adjacent electrode fingers overlap with each other when viewed in the electrode finger opposing direction is an intersecting region E. The intersecting region E is a region, which includes from the electrode finger on one end to the electrode finger on the other end in the electrode finger opposing direction, in the IDT electrode 11. More specifically, the intersecting region E includes from an outer edge portion of the electrode finger on one end in the electrode finger opposing direction to an outer edge portion of the electrode finger on the other end in the electrode finger opposing direction. The acoustic wave device 10 further includes a plurality of excitation regions C. The excitation region C is a region in which mutually-adjacent electrode fingers overlap with each other when viewed in the electrode finger opposing direction similarly to the intersecting region E. Each of the excitation regions C is a region between a pair of electrode fingers. More specifically, the excitation region C is a region from a center in the electrode finger opposing direction of one electrode finger to a center in the electrode finger opposing direction of the other electrode finger. Accordingly, the intersecting region E includes a plurality of excitation regions C.

When an AC voltage is applied to the IDT electrode 11, acoustic waves are excited in the plurality of excitation regions C. In the present preferred embodiment, the acoustic wave device 10 is configured so as to be able to use bulk waves in a thickness sliding mode, such as a thickness sliding primary mode. However, the acoustic wave device 10 may be configured to be able to use plate waves. When the acoustic wave device 10 uses plate waves, the intersecting region E is an excitation region.

Referring back to FIG. 1, in the present preferred embodiment, the acoustic wave device 10 includes a functional film 15 which entirely or substantially entirely covers the inner wall surface 13b of the support 13 and the functional film 15 has an electromagnetic-wave absorption capacity in the wavelength range from, for example, about 0.2 µm to about 1.2 µm inclusive. Here, the functional film 15 may be provided to at least a portion of the inner wall surface 13b. In the acoustic wave device 10, when acoustic waves are excited, heat is generated in the excitation regions C. At this time, a portion of the generated heat propagates in the hollow portion 13c as radiant heat F. In the present preferred embodiment, the functional film 15 is capable of effectively absorbing the radiant heat F. Further, the heat can be allowed to propagate from the functional film 15 towards the support 13 side. Thus, the acoustic wave device 10 includes an efficient heat dissipation path also in a portion in which the piezoelectric layer 14 and the support 13 are not in contact with each other. This effectively improves the heat dissipation performance.

On the other hand, emissivity of the functional film 15 is preferably higher than emissivity of the inner wall surface 13b of the support 13. Accordingly, the functional film 15 can effectively absorb the radiant heat F. In this configuration, the functional film 15 does not necessarily have to have the absorption capacity in the wavelength range from, for example, about 0.2 µm to about 1.2 µm inclusive, but may have another range of absorption capacity.

The functional film 15 preferably includes, for example, graphene, carbon nanotubes (CNT), or diamond-like carbon (DLC). Accordingly, the functional film 15 can effectively absorb the radiant heat F. The functional film 15 in this configuration does not necessarily have to have the absorption capacity in the wavelength range from, for example, about 0.2 µm to about 1.2 µm inclusive but may have another range of absorption capacity. However, it is preferable that the functional film 15 has the electromagnetic-wave absorption capacity in the wavelength range from about 0.2 µm to about 1.2 µm inclusive. This further improves the heat dissipation performance.

A first modification and a second modification of the first preferred embodiment will be described below. In the first modification and the second modification, only the position on which the functional film 15 is provided is different from that of the first preferred embodiment. A heat dissipation performance can be improved also in the first modification and the second modification as is the case with the first preferred embodiment.

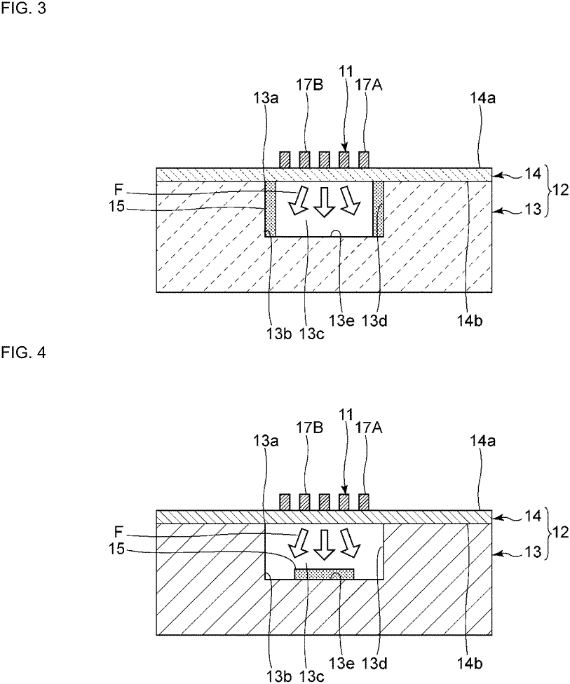

In the first modification illustrated in FIG. 3, the functional film 15 is provided on the side wall surface 13d of the inner wall surface 13b, but the functional film 15 is not provided on the bottom surface 13e. Here, the functional film 15 may be provided on a portion of the side wall surface 13d or the functional film 15 may be provided on the entire or substantially the entire surface of the side wall surface 13d. In the second modification illustrated in FIG. 4, the functional film 15 is provided on a portion of the bottom surface 13e of the inner wall surface 13b, but the functional film 15 is not provided on the side wall surface 13d. Here, the functional film 15 may be provided on the entire or substantially the entire surface of the bottom surface 13e.

FIG. 5 illustrates an example in which an acoustic wave device uses plate waves, as a third modification of the first preferred embodiment. As illustrated in FIG. 5, reflectors 18A and 18B are provided in a pair on respective sides of the IDT electrode 11 in the electrode finger opposing direction, on the first main surface 14a of the piezoelectric layer 14. This configuration can favorably improve resonance characteristics when plate waves are used. The functional film 15 in the present modification is configured similarly to that in the first preferred embodiment. Accordingly, the heat dissipation performance can be effectively improved.

A non-limiting example of a method for manufacturing the acoustic wave device 10 according to the first preferred embodiment will be described below.

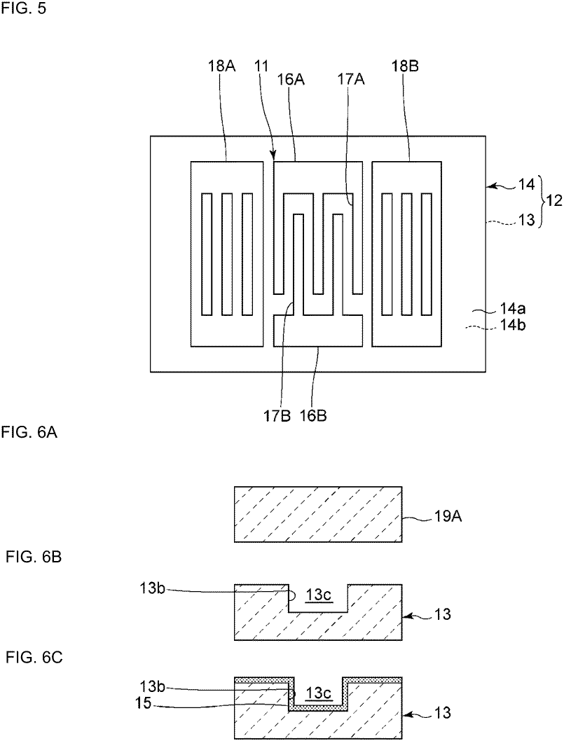

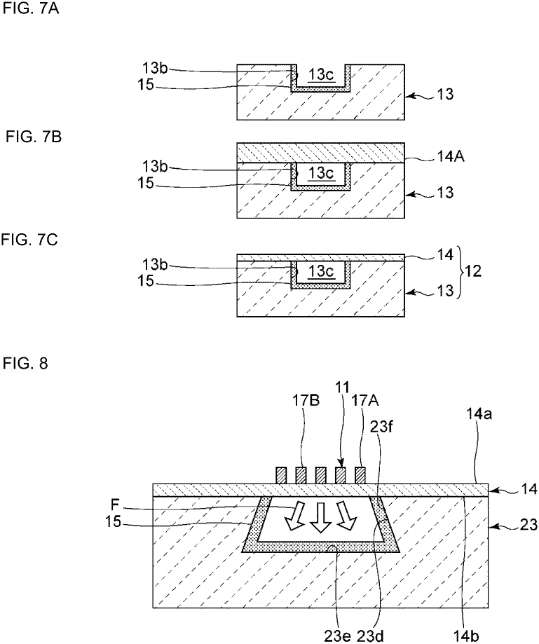

FIGS. 6A to 6C are elevational cross-sectional views for explaining a concave portion forming process and a functional film forming process in an example of a method for manufacturing an acoustic wave device according to the first preferred embodiment. FIGS. 7A to 7C are elevational cross-sectional views for explaining a functional film patterning process, a piezoelectric substrate bonding process, and a piezoelectric layer grinding process in an example of a method for manufacturing an acoustic wave device according to the first preferred embodiment.

A support substrate 19A is prepared as illustrated in FIG. 6A. Then, a concave portion is formed in the support substrate 19A so as to obtain a support substrate defining and functioning as the support 13, as illustrated in FIG. 6B. The concave portion of the support substrate is the hollow portion 13c in the first preferred embodiment. The concave portion of the support substrate can be formed by reactive ion etching (RIE), for example.

The functional film 15 is next formed by, for example, deposition as illustrated in FIG. 6C. The functional film 15 is subsequently patterned as illustrated in FIG. 7A. In the patterning of the functional film 15, an unnecessary portion in the functional film 15 may be removed by, for example, RIE. Masking may be appropriately performed with respect to a portion, which is not to be removed, of the functional film 15 by, for example, photolithography or the like.

After that, a piezoelectric substrate 14A is bonded to the support substrate defining and functioning as the support 13, as illustrated in FIG. 7B. Here, the piezoelectric substrate 14A is included in the piezoelectric layer. For example, direct bonding, plasma-activated bonding, atomic diffusion bonding, or the like can be used for the bonding of the support substrate and the piezoelectric substrate 14A. Subsequently, the thickness of the piezoelectric substrate 14A is reduced by grinding or polishing a main surface side, which is not bonded to the support substrate, of the piezoelectric substrate 14A. For example, grinding, chemical mechanical polishing (CMP), ion slicing, etching, or the like may be employed for adjusting the thickness of the piezoelectric substrate 14A. The piezoelectric layer 14 of the first preferred embodiment is thus obtained.

Then, the IDT electrode 11 is formed on the first main surface 14a of the piezoelectric layer 14 illustrated in FIG. 1 by, for example, sputtering or vacuum deposition. Here, the above-described manufacturing method is merely an example and the acoustic wave device 10 can be obtained by other methods.

FIG. 8 is an elevational cross-sectional view of an acoustic wave device according to a second preferred embodiment of the present invention.

The present preferred embodiment is different from the first preferred embodiment on the point that a side wall surface 23d of a support 23 includes an inclined portion 23f. More specifically, the inclined portion 23f is a portion that is inclined with respect to the direction in which the support 23 and the piezoelectric layer 14 are laminated. Other than the above-described point, the acoustic wave device of the present preferred embodiment has the same or substantially the same configuration as that of the acoustic wave device 10 of the first preferred embodiment.

An angle between the second main surface 14b of the piezoelectric layer 14 and the inclined portion 23f of the support 23 is obtuse. For example, it is assumed that a portion of electromagnetic waves caused by heat generation in the above-described excitation regions C is reflected by the functional film 15 which is provided on a bottom surface 23e. In this case, since the angle is obtuse, the reflected electromagnetic waves easily enter the functional film 15 provided on the inclined portion 23f. In a similar manner, electromagnetic waves reflected by the functional film 15 provided on the inclined portion 23f easily enter the functional film 15 provided on the bottom surface 23e. Electromagnetic waves can thus be confined by the functional film 15 provided on the bottom surface 23e and the inclined portion 23f. Whenever electromagnetic waves enter the functional film 15, at least a portion of the electromagnetic waves is absorbed in the range of the absorption capacity of the functional film 15. Accordingly, electromagnetic waves can be more securely absorbed by the functional film 15. That is, the functional film 15 is capable of more securely absorbing the radiant heat F. This effectively improves the heat dissipation performance.

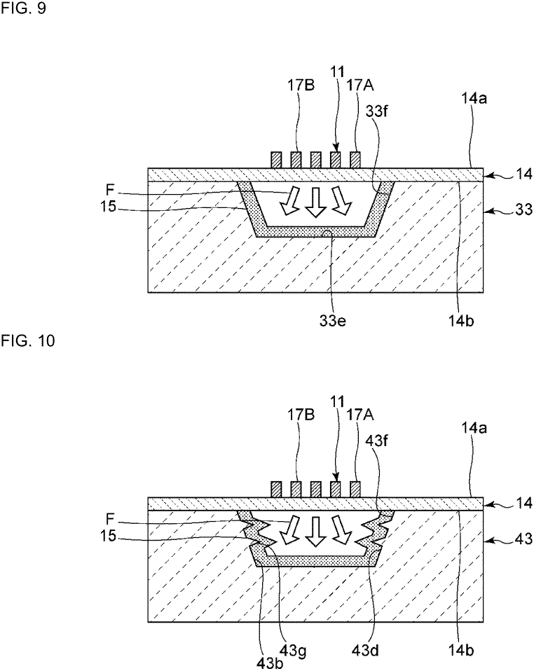

The angle between the second main surface 14b of the piezoelectric layer 14 and the inclined portion 23f of the support 23 does not have to be obtuse. In a modification of the second preferred embodiment illustrated in FIG. 9, an angle between the second main surface 14b of the piezoelectric layer 14 and an inclined portion 33f of a support 33 is acute. In this configuration, the functional film 15 provided on the inclined portion 33f can also absorb electromagnetic waves that are nearly parallel to the direction in which the support 33 and the piezoelectric layer 14 are laminated. Thus, the heat dissipation performance can be effectively improved also in the present modification. The configuration in which the angle is acute is favorable especially when the functional film 15 is not provided on a bottom surface 33e and when a hollow portion is a through hole, for example.

FIG. 10 is an elevational cross-sectional view of an acoustic wave device according to a third preferred embodiment of the present invention.

The present preferred embodiment is different from the first preferred embodiment on the point that a side wall surface 43d of a support 43 includes an inclined portion 43f and the side wall surface 43d includes a roughened portion 43g. An angle between the second main surface 14b of the piezoelectric layer 14 and the inclined portion 43f is acute. Other than the above-described point, the acoustic wave device of the present preferred embodiment has the same or substantially the same configuration as that of the acoustic wave device 10 of the first preferred embodiment.

The functional film 15 is provided on the entire or substantially the entire surface of an inner wall surface 43b of the support 43 as is the case with the first preferred embodiment. The functional film 15 accordingly includes a portion provided along the roughened portion 43g. Electromagnetic waves caused by heat generation in the above-described excitation regions C can thus be confined by the functional film 15 provided on the roughened portion 43g. Whenever electromagnetic waves enter the functional film 15, at least a portion of the electromagnetic waves is absorbed in the range of the absorption capacity of the functional film 15. Accordingly, electromagnetic waves can be more securely absorbed by the functional film 15. That is, the functional film 15 is capable of more securely absorbing the radiant heat F. This effectively improves the heat dissipation performance.

FIG. 11 is an elevational cross-sectional view of an acoustic wave device according to a fourth preferred embodiment of the present invention.

The present preferred embodiment is different from the first preferred embodiment on the point that a hollow portion 53c of a support 53 is a through hole. Other than the above-described point, the acoustic wave device of the present preferred embodiment has the same or substantially the same configuration as that of the acoustic wave device 10 of the first preferred embodiment.

An inner wall surface of the support 53 includes a side wall surface 53d but does not include a bottom surface. The functional film 15 is provided on the entire or substantially the entire surface of the side wall surface 53d. However, the functional film 15 may be provided on at least a portion of the side wall surface 53d. The present preferred embodiment can also effectively improve the heat dissipation performance as is the case with the first preferred embodiment. Here, the side wall surface 53d may include an inclined portion in the same or similar manner to the second preferred embodiment and the modification thereof. The side wall surface 53d may include a roughened portion the same as or similarly to the third preferred embodiment.

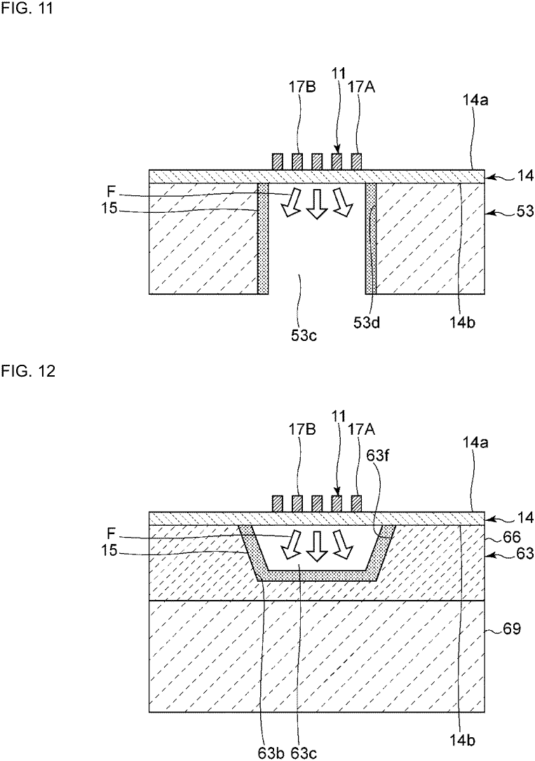

FIG. 12 is an elevational cross-sectional view of an acoustic wave device according to a fifth preferred embodiment of the present invention.

The present preferred embodiment is different from the second preferred embodiment on the point that a support 63 includes a support substrate 69 and a dielectric film 66. Here, the dielectric film 66 is an insulating layer. The dielectric film 66 is provided on the support substrate 69. The piezoelectric layer 14 is provided on the dielectric film 66. The present preferred embodiment is different from the second preferred embodiment also on the point that a hollow portion 63c is provided only in the dielectric film 66. Further, the present preferred embodiment is different from the second preferred embodiment also on the point that an angle between the second main surface 14b of the piezoelectric layer 14 and an inclined portion 63f is acute. Other than the above-described point, the acoustic wave device of the present preferred embodiment has the same or substantially the same configuration as that of the acoustic wave device of the second preferred embodiment.

The functional film 15 is provided on the entire or substantially the entire surface of an inner wall surface 63b of the support 63 also in the present preferred embodiment. However, the functional film 15 may be provided to at least a portion of the inner wall surface 63b. Electromagnetic waves caused by heat generation in the above-described excitation regions C can thus be absorbed by the functional film 15. That is, the functional film 15 is capable of absorbing the radiant heat F. Further, the heat can be allowed to propagate from the functional film 15 toward the support substrate 69 side via the dielectric film 66. This can effectively improve the heat dissipation performance.

A non-limiting example of a method for manufacturing the acoustic wave device according to the fifth preferred embodiment will be described below.

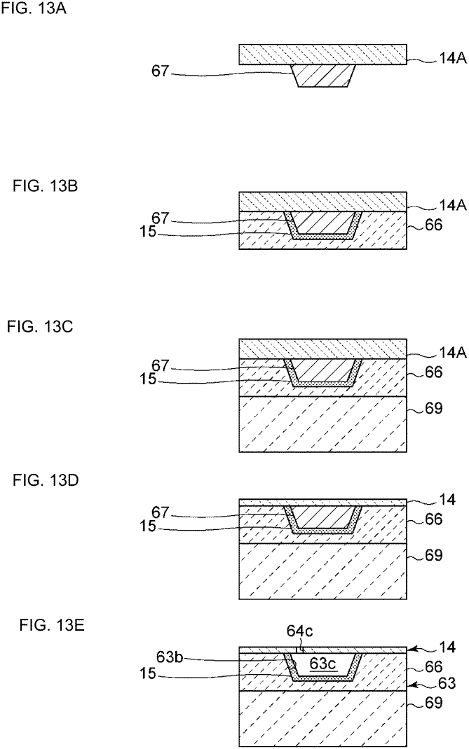

FIGS. 13A to 13E are elevational cross-sectional views for explaining an example of a method for manufacturing an acoustic wave device according to the fifth preferred embodiment.

A sacrificial layer 67 is formed on the piezoelectric substrate 14A, as illustrated in FIG. 13A. The sacrificial layer 67 is appropriately patterned by performing, for example, etching or the like. For example, ZnO, SiO₂, Cu, resin, or the like can be used as a material of the sacrificial layer 67.

The functional film 15 is next formed so as to cover the sacrificial layer 67 by, for example, deposition, as illustrated in FIG. 13B. At this time, the functional film 15 on the piezoelectric substrate 14A can be removed by appropriately patterning the functional film 15. The patterning of the functional film 15 can be performed in the same or substantially the same manner as the functional film patterning process in the example of the method for manufacturing the acoustic wave device 10 according to the first preferred embodiment.

After that, the dielectric film 66 is formed so as to cover the functional film 15. The dielectric film 66 can be formed by sputtering, vacuum deposition, or the like, for example. Then, the dielectric film 66 is planarized. For example, grinding, CMP, or the like may be used to planarize the dielectric film 66.

The support substrate 69 is next bonded to the dielectric film 66, as illustrated in FIG. 13C. Subsequently, the piezoelectric layer 14 is obtained by adjusting the thickness of the piezoelectric substrate 14A, as illustrated in FIG. 13D. The adjustment of the thickness of the piezoelectric substrate 14A can be performed in the same or substantially the same manner as the piezoelectric layer grinding process in the example of the method for manufacturing the acoustic wave device 10 according to the first preferred embodiment.

A through hole 64c illustrated in FIG. 13E is next formed in the piezoelectric layer 14 so that the through hole 64c extends to the sacrificial layer 67. The through hole 64c can be formed by RIE, for example. Subsequently, the sacrificial layer 67 is removed via the through hole 64c. More specifically, the sacrificial layer 67 in the concave portion of the dielectric film 66 is removed by, for example, allowing etchant to flow in from the through hole 64c. The hollow portion 63c is thus formed. Then, the IDT electrode 11 is formed on the first main surface 14a of the piezoelectric layer 14 illustrated in FIG. 12 by, for example, sputtering or vacuum deposition. However, the above-described manufacturing method is merely an example and the acoustic wave device of the fifth preferred embodiment can be obtained by other methods.

Here, a hollow portion may be formed in at least one of the support substrate 69 and the dielectric film 66 in the support 63. In a modification of the fifth preferred embodiment illustrated in FIG. 14, a hollow portion is a through hole penetrating through a support substrate 69A and a dielectric film 66A. An inner wall surface of a support 63A includes a side wall surface but does not include a bottom surface. More specifically, the side wall surface of the support 63A is a side wall surface 69d of the support substrate 69A and a side wall surface 66d of the dielectric film 66A. The functional film 15 is provided on the entire or substantially the entire surfaces of the side wall surface 69d of the support substrate 69A and the side wall surface 66d of the dielectric film 66A. The heat dissipation performance can be effectively improved also in the present modification. Here, the functional film 15 may be provided on at least a portion of the side wall surface of the support 63A, as is the case with the fifth preferred embodiment. This side wall surface may include an inclined portion or a roughened portion.

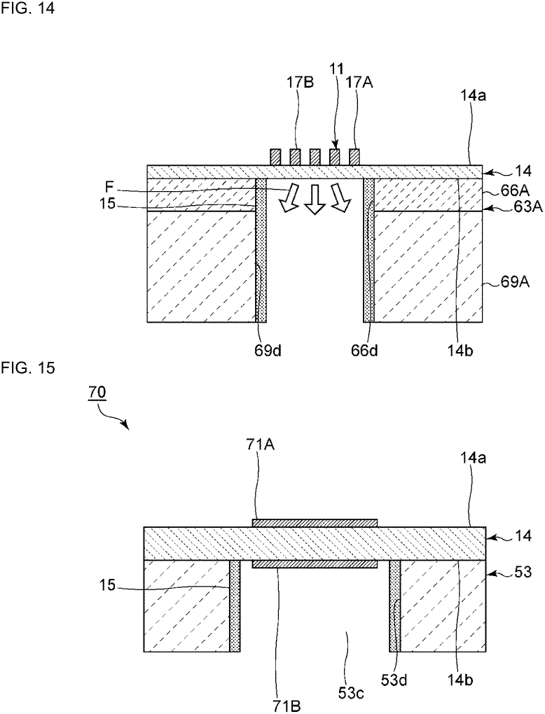

FIG. 15 is an elevational cross-sectional view of an acoustic wave device according to a sixth preferred embodiment of the present invention.

The present preferred embodiment is different from the fourth preferred embodiment on the point that an excitation electrode includes an upper electrode 71A and a lower electrode 71B. An acoustic wave device 70 is, for example, a bulk acoustic wave (BAW) element. Other than the above-described point, the acoustic wave device 70 of the present preferred embodiment has the same or substantially the same configuration as that of the acoustic wave device of the fourth preferred embodiment.

The upper electrode 71A is provided on the first main surface 14a of the piezoelectric layer 14. The lower electrode 71B is provided on the second main surface 14b of the piezoelectric layer 14. The upper electrode 71A and the lower electrode 71B are opposed to each other with the piezoelectric layer 14 interposed therebetween. The upper electrode 71A and the lower electrode 71B are connected to mutually-different potentials. In the present preferred embodiment, a region in which the upper electrode 71A and the lower electrode 71B are opposed to each other is an excitation region. The hollow portion 53c of the support 53 overlaps with the excitation region in plan view. Accordingly, at least a portion of the upper electrode 71A and the lower electrode 71B overlaps with the hollow portion 53c in plan view.

The functional film 15 is provided on the entire or substantially the entire surface of the side wall surface 53d also in the present preferred embodiment, as is the case with the fourth preferred embodiment. This can effectively improve the heat dissipation performance.

An acoustic wave device using bulk waves in a thickness sliding mode will be described in detail below.

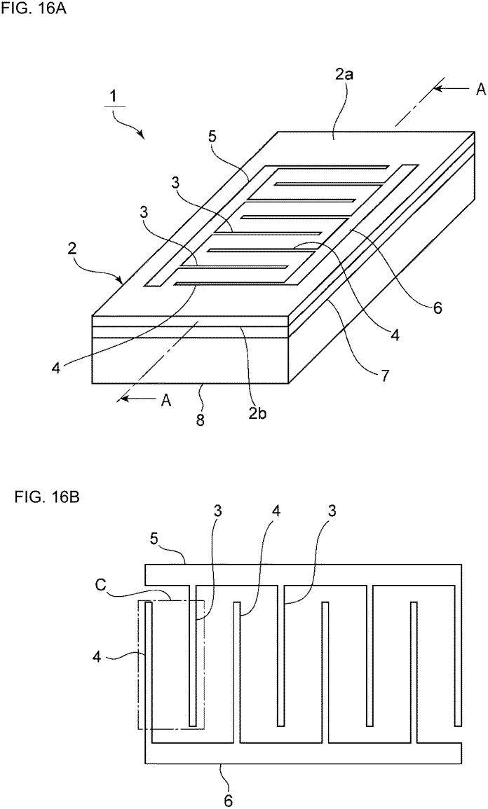

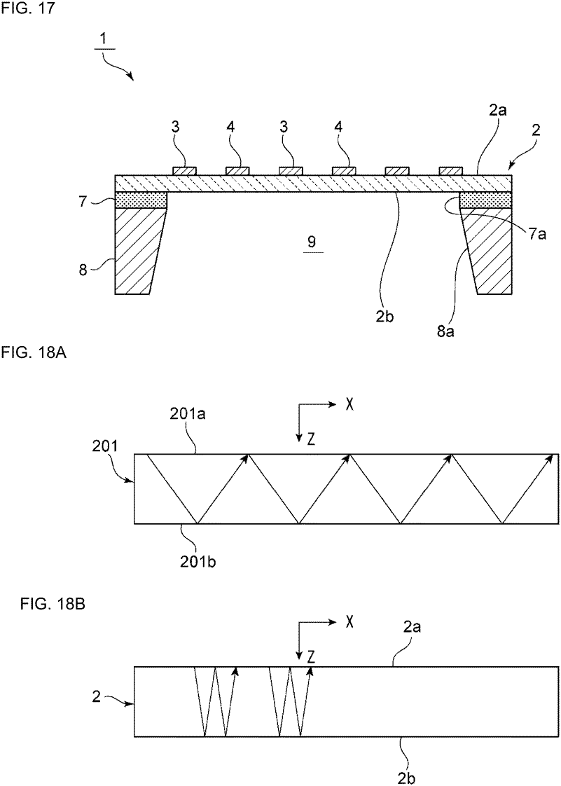

FIG. 16A is a simplified perspective view illustrating an outer appearance of an acoustic wave device using bulk waves in thickness sliding mode, and FIG. 16B is a plan view illustrating an electrode structure on a piezoelectric layer. FIG. 17 is a sectional view of a portion taken along an A-A line of FIG. 16A.

An acoustic wave device 1 includes a piezoelectric layer 2 made of, for example, LiNbO₃. The piezoelectric layer 2 may be made of, for example, LiTaO₃ instead. A cut-angle of LiNbO₃ and LiTaO₃ is Z-cut, but the cut-angle may be rotated Y-cut or X-cut. Not especially limited, the thickness of the piezoelectric layer 2 is preferably, for example, from about 40 nm to about 1000 nm inclusive, and more preferably from about 50 nm to about 1000 nm inclusive, so as to obtain effective excitation in the thickness sliding mode. The piezoelectric layer 2 includes a first main surface 2a and a second main surface 2b that are opposed to each other. An electrode 3 and an electrode 4 are provided on the first main surface 2a. Here, the electrode 3 is an example of the “first electrode” and the electrode 4 is an example of the “second electrode”. In FIG. 16A and FIG. 16B, a plurality of electrodes 3 are connected to a first busbar 5. A plurality of electrodes 4 are connected to a second busbar 6. The plurality of electrodes 3 and the plurality of electrodes 4 are interdigitated. The electrode 3 and the electrode 4 have a rectangular or substantially rectangular shape and includes a longitudinal direction. In a direction orthogonal or substantially orthogonal to the longitudinal direction, the electrode 3 and adjacent electrode 4 are opposed to each other. Both of the longitudinal direction of the electrodes 3 and 4 and the direction orthogonal or substantially orthogonal to the longitudinal direction of the electrodes 3 and 4 are directions intersecting with the thickness direction of the piezoelectric layer 2. Therefore, it can be said that the electrode 3 and the adjacent electrode 4 are opposed to each other in the direction intersecting with the thickness direction of the piezoelectric layer 2. Here, the longitudinal direction of the electrodes 3 and 4 may be exchanged with the direction orthogonal or substantially orthogonal to the longitudinal direction of the electrodes 3 and 4 illustrated in FIGS. 16A and 16B. Namely, the electrodes 3 and 4 may extend in a direction in which the first busbar 5 and the second busbar 6 extend in FIGS. 16A and 16B. In this configuration, the first busbar 5 and the second busbar 6 extend in the direction in which the electrodes 3 and 4 extend in FIGS. 16A and 16B. A plurality of structures, each of which includes a pair of mutually-adjacent electrodes 3 and 4, are provided in the direction orthogonal or substantially orthogonal to the longitudinal direction of the electrodes 3 and 4. In the structure, the electrode 3 is connected to one potential and the electrode 4 is connected to the other potential. Here, the state in which the electrode 3 and the electrode 4 are mutually adjacent is not the state in which the electrode 3 and the electrode 4 are arranged to be in direct contact with each other but the state in which the electrode 3 and the electrode 4 are arranged with an interval therebetween. Further, when the electrode 3 and the electrode 4 are mutually adjacent, any other electrodes, as well as other electrodes 3 and 4, connected to a hot electrode or a ground electrode are not arranged between these mutually-adjacent electrodes 3 and 4. The number of pairs does not have to be an integer but the pairs may be 1.5 pairs or 2.5 pairs, for example. The distance between the centers of the electrodes 3 and 4, that is, the pitch is preferably, for example, in a range from about 1 µm to about 10 µm inclusive. The width of the electrodes 3 and 4, namely, the dimension in the opposing direction of the electrodes 3 and 4 is preferably, for example, in a range from about 50 nm to about 1000 nm inclusive, more preferably in a range from about 150 nm to about 1000 nm inclusive. The distance between the centers of the electrodes 3 and 4 is the distance obtained by connecting the center of the electrode 3 in the dimension (width dimension) in the direction orthogonal to the longitudinal direction of the electrode 3 and the center of the electrode 4 in the dimension (width dimension) in the direction orthogonal or substantially orthogonal to the longitudinal direction of the electrode 4 with each other.

The acoustic wave device 1 uses the Z-cut piezoelectric layer and therefore, the direction orthogonal or substantially orthogonal to the longitudinal direction of the electrodes 3 and 4 is a direction orthogonal or substantially orthogonal to a polarization direction of the piezoelectric layer 2. This does not apply when piezoelectric materials of other cut-angles are used as the piezoelectric layer 2. Here, “orthogonal” is not limitedly used for the exactly orthogonal configuration but may be used for the substantially orthogonal configuration (within the range about 90°±10°, for example, of an angle formed by the direction orthogonal to the longitudinal direction of the electrodes 3 and 4 and a polarization direction).

A support 8 is laminated on the second main surface 2b side of the piezoelectric layer 2 with an insulation layer 7 interposed therebetween. The insulation layer 7 and the support 8 have a frame shape and include through holes 7a and 8a respectively as illustrated in FIG. 17. A hollow portion 9 is thus provided. The hollow portion 9 does not disturb vibration in the excitation region C of the piezoelectric layer 2. Therefore, the support 8 is laminated on the second main surface 2b with the insulation layer 7 interposed therebetween, on a position which does not overlap with a portion provided with at least a pair of electrodes 3 and 4. Here, the insulation layer 7 does not necessarily have to be provided. Thus, the support 8 can be directly or indirectly laminated on the second main surface 2b of the piezoelectric layer 2.

The insulation layer 7 is made of, for example, silicon oxide. Also, an appropriate insulating material such as, for example, silicon oxynitride and alumina can be used as well as silicon oxide. The support 8 is made of, for example, Si. A plane orientation of Si on a surface on the piezoelectric layer 2 side may be (100), (110), and (111). Si of the support 8 preferably has a high resistivity of, for example, about 4 kΩ or higher. The support 8 can also be made of an appropriate insulating material or semiconductor material.

Examples used as the material of the support 8 include piezoelectric materials such as aluminum oxide, lithium tantalate, lithium niobate, and crystal, various ceramics such as alumina, magnesia, sapphire, silicon nitride, aluminum nitride, silicon carbide, zirconia, cordierite, mullite, steatite, and forsterite; dielectrics such as diamond and glass, and semiconductors such as gallium nitride.

The plurality of electrodes 3 and 4 and the first and second busbars 5 and 6 are made of appropriate metal or alloy such as, for example, Al and AlCu alloy. In the present preferred embodiment, the electrodes 3 and 4 and the first and second busbars 5 and 6 have a structure including, for example, an Al film laminated on a Ti film. However, an adhesion layer other than the Ti film may be used.

An AC voltage is applied between the plurality of electrodes 3 and the plurality of electrodes 4 for driving. More specifically, an AC voltage is applied between the first busbar 5 and the second busbar 6. This can provide resonance characteristics using bulk waves in the thickness sliding mode that are excited in the piezoelectric layer 2. When the thickness of the piezoelectric layer 2 is d and the distance between centers of any mutually-adjacent electrodes 3 and 4 among the plurality of pairs of electrodes 3 and 4 is p, d/p is, for example, about 0.5 or lower in the acoustic wave device 1. Therefore, bulk waves in the thickness sliding mode are effectively excited and favorable resonance characteristics can be obtained. d/p is more preferably, for example, about 0.24 or lower, which can provide more favorable resonance characteristics.

Since the acoustic wave device 1 has the above-described configuration, a Q value is not easily lowered even when the number of pairs of electrodes 3 and 4 is reduced to promote downsizing. This is because propagation loss is small even when reducing the number of electrode fingers in reflectors on both sides. Further, the number of electrode fingers can be reduced because of the use of bulk waves in the thickness sliding mode. The difference between Lamb waves used in an acoustic wave device and bulk waves in the thickness sliding mode described above will be described with reference to FIGS. 18A and 18B.

FIG. 18A is a schematic elevational cross-sectional view for explaining Lamb waves propagating through a piezoelectric film of an acoustic wave device as the one described in Japanese Unexamined Patent Application Publication No. 2012-257019. Here, waves propagate in a piezoelectric film 201 as illustrated with arrows. A first main surface 201a and a second main surface 201b are opposed to each other in the piezoelectric film 201, and a thickness direction connecting the first main surface 201a and the second main surface 201b is the Z direction. The X direction is a direction in which electrode fingers of an IDT electrode are aligned. As illustrated in FIG. 18A, in Lamb waves, the waves propagate in the X direction. Even though the entire piezoelectric film 201 vibrates, the waves propagate in the X direction because the waves are plate waves. Therefore, reflectors are arranged on both sides so as to obtain resonance characteristics. Consequently, wave propagation loss is generated, and when downsizing is promoted, namely, when the number of pairs of electrode fingers is reduced, a Q value is lowered.

On the other hand, vibration displacement is in a thickness sliding direction in the acoustic wave device 1. Therefore, waves mostly propagate and resonate in the direction connecting the first main surface 2a and the second main surface 2b of the piezoelectric layer 2, namely, in the Z direction as illustrated in FIG. 18B. That is, X-direction components of the waves are remarkably smaller than Z-direction components. Resonance characteristics can be obtained by this wave propagation in the Z direction and therefore, propagation loss is not likely to be generated even when the number of electrode fingers of reflectors is reduced. Further, even when the number of pairs of electrodes composed of the electrodes 3 and 4 is reduced to promote downsizing, a Q value is not easily lowered.

An amplitude direction of a bulk wave in the thickness sliding mode is reversed between a first region 451 included in the excitation region C of the piezoelectric layer 2 and a second region 452 included in the excitation region C, as illustrated in FIG. 19. FIG. 19 schematically illustrates a bulk wave obtained when applying a voltage, by which the electrode 4 has a higher potential than the electrode 3, between the electrode 3 and the electrode 4. The first region 451 is a region between a virtual plane VP1, which is orthogonal or substantially orthogonal to the thickness direction of the piezoelectric layer 2 and divides the piezoelectric layer 2 into two, and the first main surface 2a, in the excitation region C. The second region 452 is a region between the virtual plane VP1 and the second main surface 2b, in the excitation region C.

In the acoustic wave device 1, at least one pair of electrodes including the electrode 3 and the electrode 4 is provided, as described above. However, waves do not propagate in the X direction in the acoustic wave device 1 and therefore, the number of pairs of electrodes including the electrodes 3 and 4 does not have to be plural. That is, it is sufficient if at least one pair of electrodes is provided.

For example, the electrode 3 is an electrode connected to a hot potential and the electrode 4 is an electrode connected to a ground potential. However, the electrode 3 may be connected to a ground potential and the electrode 4 may be connected to a hot potential. In the present preferred embodiment, at least one pair of electrodes is an electrode connected to a hot potential or an electrode connected to a ground potential as mentioned above, and no floating electrodes are provided.

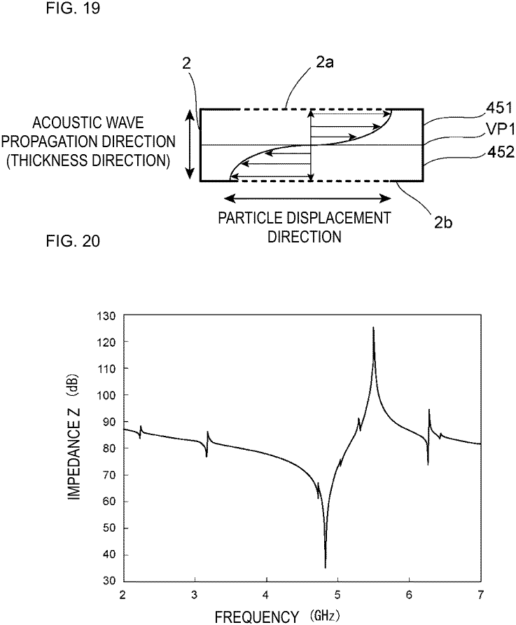

FIG. 20 is a diagram illustrating resonance characteristics of the acoustic wave device illustrated in FIG. 17. The followings are the design parameters of the acoustic wave device 1 having the resonance characteristics.

Piezoelectric layer 2: LiNbO₃ of Euler angles (about 0°, about 0°, about 90°), thickness = about 400 nm

A region in which the electrode 3 and the electrode 4 overlap with each other when viewed in the direction orthogonal or substantially orthogonal to the longitudinal direction of the electrode 3 and the electrode 4, namely, the length of the excitation region C = about 40 µm, the number of pairs of electrodes composed of the electrodes 3 and 4 = 21 pairs, the distance between centers of electrodes = about 3 µm, the width of the electrodes 3 and 4 = 500 nm, d/p = about 0.133.

Insulation layer 7: a silicon oxide film having the thickness of about 1 µm.

Support 8: Si.

The length of the excitation region C is a dimension of the excitation region C along the longitudinal direction of the electrodes 3 and 4.

The present preferred embodiment includes the configuration in which the inter-electrode distances among a plurality of pairs of electrodes composed of the electrodes 3 and 4 are all equal to each other. That is, the electrodes 3 and the electrodes 4 are arranged at equal or substantially equal pitches.

As is apparent from FIG. 20, favorable resonance characteristics in which a fractional bandwidth is about 12.5% can be obtained even without providing reflectors.

Here, when the thickness of the piezoelectric layer 2 is d and the distance between electrode centers of the electrodes 3 and 4 is p, d/p is about 0.5 or lower, and more preferably about 0.24 or lower as described above, in the present preferred embodiment. This will be described with reference to FIG. 21.

A plurality of acoustic wave devices that are similar to the acoustic wave device having the resonance characteristics illustrated in FIG. 20 were obtained, in which d/p was changed. FIG. 21 is a diagram illustrating a relation between the d/p and fractional bandwidths of the acoustic wave devices as resonators.

As is apparent from FIG. 21, when d/p > about 0.5, the fractional bandwidth is less than about 5% even when d/p is adjusted. In contrast to this, when d/p ≤ about 0.5, the fractional bandwidth can be set to about 5% or greater if d/p is changed within this range, namely a resonator having a high coupling coefficient can be configured. Further, when d/p is about 0.24 or lower, the fractional bandwidth can be increased to about 7% or greater. In addition to this, if d/p is adjusted within this range, a resonator having a wider fractional bandwidth can be obtained, accordingly being able to realize a resonator having a higher coupling coefficient. Thus, it is shown that a resonator which uses bulk waves in the thickness sliding mode and has a high coupling coefficient can be configured by setting d/p to about 0.5 or lower.

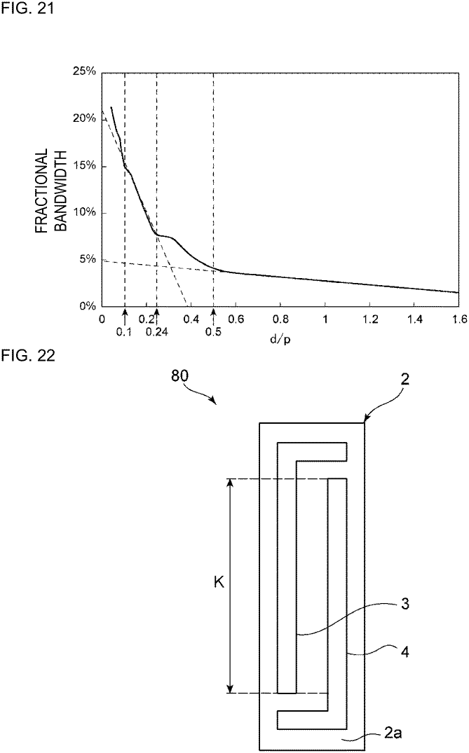

FIG. 22 is a plan view of an acoustic wave device using bulk waves in the thickness sliding mode. In an acoustic wave device 80, a pair of electrodes including the electrode 3 and the electrode 4 is provided on the first main surface 2a of the piezoelectric layer 2. Here, K in FIG. 22 denotes an intersecting width. The number of pairs of electrodes may be one in the acoustic wave device of the present invention, as described above. In this configuration as well, bulk waves in the thickness sliding mode can be effectively excited if is, for example, about 0.5 or lower.

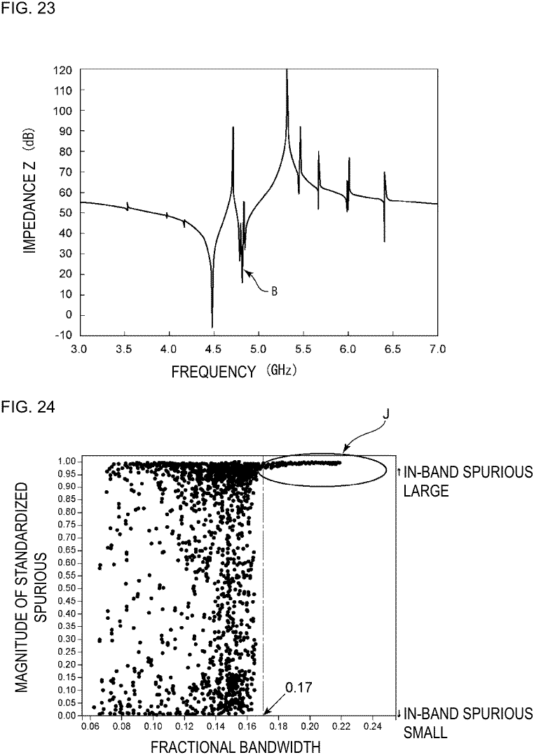

In the acoustic wave device 1, any mutually-adjacent electrodes 3 and 4 among the plurality of electrodes 3 and 4 preferably have a metallization ratio MR that satisfies MR ≤ about 1.75(d/p)+0.075, with respect to the excitation region C, which is a region in which the mutually-adjacent electrodes 3 and 4 overlap with each other when viewed in the opposing direction thereof. This configuration can effectively reduce or prevent spurious responses. This will be described with reference to FIG. 23 and FIG. 24. FIG. 23 is a reference diagram illustrating an example of resonance characteristics of the acoustic wave device 1 described above. A spurious response shown with an arrow B is seen between a resonant frequency and an anti-resonant frequency. Here, it is defined that d/p = about 0.08 and Euler angles of LiNbO₃ is (about 0°, about 0°, about 90°). Further, the metallization ratio MR mentioned above is defined as MR = about 0.35.

The metallization ratio MR will be described with reference to FIG. 16B. Focusing on one pair of electrodes 3 and 4 in the electrode structure of FIG. 16B, it is assumed that only this pair of electrodes 3 and 4 is provided. In this case, a portion enclosed by a dashed-dotted line is the excitation region C. This excitation region C is a region of the electrode 3 which overlaps with the electrode 4, a region of the electrode 4 which overlaps with the electrode 3, and a region in which the electrode 3 and the electrode 4 overlap with each other in a region between the electrode 3 and the electrode 4, when the electrode 3 and the electrode 4 are viewed in the direction orthogonal or substantially orthogonal to the longitudinal direction of the electrodes 3 and 4, that is, in the opposing direction of the same. An area of the electrodes 3 and 4 in the excitation region C with respect to an area of the excitation region C is the metallization ratio MR. Namely, the metallization ratio MR is a ratio of an area of a metallization portion with respect to the area of the excitation region C.

When a plurality of pairs of electrodes are provided, MR may be set to a rate of metallization portions included in all excitation regions with respect to a total of areas of the excitation regions.

FIG. 24 is a diagram illustrating a relationship between fractional bandwidths obtained in configuring a multitude of acoustic wave resonators and phase rotation amounts of impedance of spurious which is standardized at 180 degrees as the magnitudes of spurious, in accordance with the present preferred embodiment. Here, the fractional bandwidths were adjusted by variously changing the film thickness of piezoelectric layers and the dimensions of electrodes. FIG. 23 illustrates a result obtained when the piezoelectric layer made of Z-cut LiNbO₃ was used, but the same or similar tendency is obtained also when piezoelectric layers of other cut-angles are used.

A region enclosed with an ellipse J in FIG. 24 has a large spurious response which is about 1.0. Apparent from FIG. 24, when the fractional bandwidth exceeds about 0.17, that is, exceeds about 17%, a large spurious response whose spurious level is about 1 or greater appears in a pass band even when parameters defining the fractional bandwidth are changed. In other words, a large spurious response indicated by the arrow B appears in a band as resonance characteristics illustrated in FIG. 23. Thus, the fractional bandwidth is preferably about 17% or less. In this case, spurious responses can be reduced by adjusting the film thickness of the piezoelectric layer 2 and the dimensions of the electrodes 3 and 4, for example.

FIG. 25 is a diagram illustrating a relationship among d/2p, metallization ratio MR, and fractional bandwidth. In terms of the acoustic wave device described above, various acoustic wave devices mutually having different d/2p and MR were configured and fractional bandwidths were measured. A hatched portion on the right side of a dashed line D in FIG. 25 is a region in which the fractional bandwidth is about 17% or less. A boundary between the hatched region and a non-hatched region is expressed as MR = about 3.5(d/2p)+0.075. That is, MR = about 1.75(d/p)+0.075 is established. Accordingly, MR ≤ about 1.75(d/p)+0.075 is preferably established. This makes it easier to set the fractional bandwidth to about 17% or less. A region on the right side of MR = about 3.5(d/2p) +0.05 indicated by a dashed-dotted line D1 in FIG. 25 is more preferable. Namely, when MR ≤ about 1.75(d/p)+0.05 is established, the fractional bandwidth can be securely set to about 17% or less.

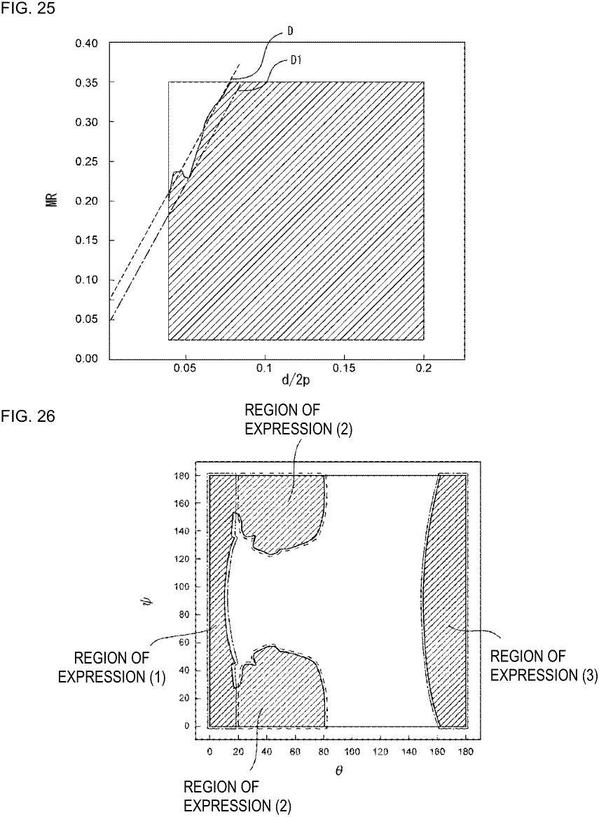

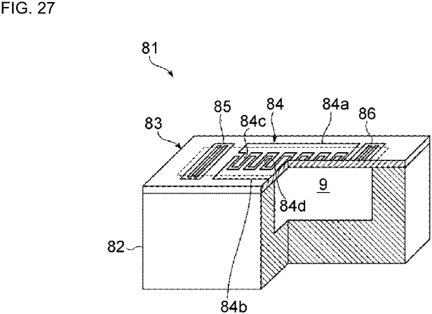

FIG. 26 is a diagram showing a map of a fractional bandwidth with respect to Euler angles (0°, Θ, ψ) of LiNbO₃, which is obtained by approximating d/p to 0 as much as possible. Hatched portions in FIG. 26 are regions in which a fractional bandwidth of at least about 5% or greater can be obtained, and when ranges of the regions are approximated, ranges expressed by the following Expression (1), Expression (2), and Expression (3) are obtained.

$$\left(0 ° \pm 10 ° , 0 ° \text{to} 20 ° , \text{arbitrary} \text{ψ}\right) \qquad \text{(1)}$$

$$\begin{matrix}\left(0 ° \pm 10 ° , 20 ° \text{to} 80 ° , 0 ° \text{to} 60 ° {\left(1 - {\left(\text{θ} - 50\right)}^{2} / 900\right)}^{1 / 2}\right) \text{or} \\ \left(0 ° \pm 10 ° , 20 ° \text{to} 80 ° , \left[180 ° - 60 ° {\left(1 - {\left(\text{θ} - 50\right)}^{2} / 900\right)}^{1 / 2}\right] \text{to} 180 °\right)\end{matrix} \qquad \text{(2)}$$

$$\left(0 ° \pm 10 ° , \left[180 ° - 30 ° {\left(1 - {\left(\text{ψ−90}\right)}^{2} / 8100\right)}^{1 / 2}\right] \text{to} 180 ° , \text{arbitrary} \text{ψ}\right) \qquad \text{(3)}$$

Thus, in the Euler-angle ranges of Expression (1), Expression (2), or Expression (3) above, the fractional bandwidth can be sufficiently favorably expanded. The same applies to a configuration in which the piezoelectric layer 2 is a lithium tantalate layer.

FIG. 27 is a partial cutout perspective view for explaining an acoustic wave device according to a preferred embodiment of the present invention.

An acoustic wave device 81 includes a support substrate 82. The support substrate 82 includes an open concave portion on the top surface. A piezoelectric layer 83 is laminated on the support substrate 82. Accordingly, the hollow portion 9 is provided. An IDT electrode 84 is provided on the piezoelectric layer 83 above the hollow portion 9. Reflectors 85 and 86 are provided on respective sides in an acoustic wave propagation direction of the IDT electrode 84. FIG. 27 indicates an outer circumferential edge of the hollow portion 9 with a dashed line. In this example, the IDT electrode 84 includes a first busbar 84a, a second busbar 84b, a plurality of first electrode fingers 84c, and a plurality of second electrode fingers 84d. The plurality of first electrode fingers 84c are connected to the first busbar 84a. The plurality of second electrode fingers 84d are connected to the second busbar 84b. The plurality of first electrode fingers 84c and the plurality of second electrode fingers 84d are interdigitated.

In the acoustic wave device 81, Lamb waves as plate waves are excited by applying an AC electric field to the IDT electrode 84 provided above the hollow portion 9. Since the reflectors 85 and 86 are provided on the both sides, resonance characteristics based on the Lamb waves can be obtained.

Thus, the acoustic wave device of the present preferred embodiment may use plate waves.

In the piezoelectric board in the acoustic wave device of each of the first to fifth preferred embodiments and modifications using bulk waves in the thickness sliding mode, d/p is preferably, for example, about 0.24 or lower as described above. This configuration can provide more favorable resonance characteristics. Further, in the acoustic wave device of each of the first to fifth preferred embodiments and modifications using bulk waves in the thickness sliding mode, MR ≤ about 1.75(d/p)+0.075 is preferably satisfied as described above. This configuration can more securely reduce or prevent spurious responses.

The piezoelectric layer in the acoustic wave device of each of the first to fifth preferred embodiments and modifications using bulk waves in the thickness sliding mode is preferably, for example, a lithium niobate layer or a lithium tantalate layer. Euler angles (φ, Θ, ψ) of lithium niobate or lithium tantalate constituting the piezoelectric layer are preferably within the ranges of Expression (1), Expression (2), or Expression (3) mentioned above. This configuration can sufficiently expand the fractional bandwidth.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support including a support substrate;
a piezoelectric layer on the support; and
an excitation electrode on the piezoelectric layer; wherein
a hollow portion is provided in the support and overlaps with at least a portion of the excitation electrode in plan view;
the support includes a cavity opening on a side of the piezoelectric layer, and an inner wall surface connected to the cavity and facing the hollow portion; and
a functional film is provided on at least a portion of the inner wall surface and has an electromagnetic-wave absorption capacity in a wavelength range from about 0.2 µm to about 1.2 µm inclusive.

2. An acoustic wave device comprising:
a support including a support substrate;
a piezoelectric layer on the support; and
an excitation electrode on the piezoelectric layer; wherein
a hollow portion is provided in the support and overlaps with at least a portion of the excitation electrode in plan view;
the support includes a cavity opening on a side of the piezoelectric layer, and an inner wall surface connected to the cavity and facing the hollow portion;
a functional film is provided on at least a portion of the inner wall surface; and
emissivity of the functional film is higher than emissivity of the inner wall surface of the support.

3. An acoustic wave device comprising:
a support including a support substrate;
a piezoelectric layer on the support; and
an excitation electrode on the piezoelectric layer; wherein
a hollow portion is provided in the support and overlaps with at least a portion of the excitation electrode in plan view;
the support includes a cavity opening on a side of the piezoelectric layer, and an inner wall surface connected to the cavity and facing the hollow portion;
a functional film is provided, on at least a portion of the inner wall surface; and
the functional film includes graphene, carbon nanotubes, or diamond-like carbon.

4. The acoustic wave device according to claim 1, wherein the support includes the support substrate and a dielectric film between the support substrate and the piezoelectric layer.

5. The acoustic wave device according to claim 1, wherein the support includes only the support substrate.

6. The acoustic wave device according to claim 1, wherein
the inner wall surface includes a side wall surface connected to the cavity; and
the side wall surface includes an inclined portion inclined with respect to a direction in which the support and the piezoelectric layer are laminated.

7. The acoustic wave device according to claim 1, wherein
the inner wall surface includes a side wall surface connected to the cavity; and
the side wall surface includes a roughened portion.

8. The acoustic wave device according to claim 1, wherein the inner wall surface includes a side wall surface connected to the cavity, and a bottom surface connected with the side wall surface and opposed to the piezoelectric layer.

9. The acoustic wave device according to claim 1, wherein the hollow portion is a through hole penetrating through the support.

10. The acoustic wave device according to claim 1, wherein the functional film covers a entirety or substantially an entirety of the inner wall surface.

11. The acoustic wave device according to claim 1, wherein the excitation electrode is an IDT electrode including a plurality of electrode fingers.

12. The acoustic wave device according to claim 11, wherein the acoustic wave device is operable to generate a plate wave.

13. The acoustic wave device according to claim 11, wherein the acoustic wave device is operable to generate a bulk wave in a thickness sliding mode.

14. The acoustic wave device according to claim 11, wherein, when a thickness of the piezoelectric layer is d and a distance between centers of the electrode fingers adjacent to each other, is p, d/p is about 0.5 or lower.

15. The acoustic wave device according to claim 14, wherein d/p is about 0.24 or lower.

16. The acoustic wave device according to claim 14, wherein a region in which the electrode fingers adjacent to each other overlap with each other when viewed in a direction in which the electrode fingers are opposed to each other is an excitation region, and, when a metallization ratio of the plurality of electrode fingers with respect to the excitation region is MR, MR ≤ about 1.75(d/p)+0.075 is satisfied.

17. The acoustic wave device according to claim 1, wherein
the piezoelectric layer includes a first main surface and a second main surface opposed to each other;
the excitation electrode includes an upper electrode on the first main surface of the piezoelectric layer and a lower electrode on the second main surface; and
the upper electrode and the lower electrode are opposed to each other with the piezoelectric layer interposed therebetween.

18. The acoustic wave device according to claim 1, wherein the piezoelectric layer is a lithium tantalate layer or a lithium niobate layer.

19. The acoustic wave device according to claim 13, wherein
the piezoelectric layer is a lithium tantalate layer or a lithium niobate layer; and
Euler angles (φ, θ, ψ) of lithium tantalate or lithium niobate constituting the piezoelectric layer are within a range of Expression (1), Expression (2), or Expression (3):
$$\left(0 ° \pm 10 ° , \text{0} ° \text{to 20} ° \text{, arbitrary} ψ\right) \qquad \text{(1)}$$
$$\begin{matrix}\left(0 ° \pm 10 ° , \text{20} ° \text{to 80} ° \text{, 0} ° \text{to 60} ° {\left(1 - {\left(θ - 50\right)}^{2} / 900\right)}^{1 / 2}\right) \text{or} \left(\text{0} ° \pm \right) \\ \left(\text{10} ° \text{, 20} ° \text{to 80} ° \text{,} \left[180 ° - 60 ° {\left(1 - {\left(θ - 50\right)}^{2} / 900\right)}^{1 / 2}\right] \text{to 180} °\right)\end{matrix} \qquad \text{(2)}$$
and
$$\begin{matrix}\left(\text{0} ° \pm \text{10} ° \text{,} \left[180 ° - 30 ° {\left(1 - {\left(ψ - 90\right)}^{2} / 8100\right)}^{1 / 2}\right] \text{to 180} ° \text{, arbitrary}\right) \\ \left(ψ\right)\end{matrix} \qquad \text{(3)}$$
.
